(19) United States
(12) Patent Application Publication
(10) Pub. No.: US 2025/0294714 A1
(43) Pub. Date: Sep. 18, 2025

(54) HEAT SINK WITH PIN FINS AND NON-STRAIGHT CONSTANT VOLUME FLOW CHANNEL

(71) Applicant: Parker-Hannifin Corporation, Cleveland, OH (US)

(72) Inventors: Nithin Gangadharan, Mayfield Heights, OH (US); Brandon J. Wegmann, Indian Trail, NC (US)

(73) Assignee: Parker-Hannifin Corporation, Cleveland, OH (US)

(21) Appl. No.: 18/861,384

(22) PCT Filed: Apr. 18, 2023
(86) PCT No.: PCT/US2023/018929

§ 371 Date: Oct. 29, 2024

Related U.S. Application Data
(60) Provisional application No. 63/347,666, filed on Jun. 1, 2022.
(60) Provisional application No. 63/396,329, filed on Aug. 9, 2022.

(51) Int. Cl. H05K 7/20; F28F 3/02

(52) U.S. Cl. CPC H05K 7/20927; F28F 3/022; H05K 7/209

(57) ABSTRACT

A heat sink includes a heat sink body that defines a fluid channel to receive a flow of a cooling fluid. The heat sink body includes a channel base and a channel wall that extends from the channel base to define the fluid channel, the channel wall having a plurality of wall segments that form a non-straight channel wall profile. An array of pin fins is located within the fluid channel and extends from the channel base, the channel wall being located peripherally relative to the array of pin fins. The plurality of wall segments may be configured as adjacent semicircular wall segments that form a wavy channel wall profile, and/or the pin fins may be cylindrical pin fins having a circular cross-sectional shape, although other shape combinations may be employed. The channel wall and the array of pin fins are positioned such that there is a constant flow area for the flow of the cooling fluid across each row and column of the array of pin fins.

### RELATED APPLICATIONS

This application claims the benefit of U.S. Provisional Application No. 63/347,666 filed on Jun. 1, 2022, and U.S. Provisional Application No. 63/396,329 filed on Aug. 9, 2022, the contents of which are incorporated here by reference.

### FIELD OF INVENTION

The present application relates generally to fluid cooled heat sinks, such as may be used for the cooling of electronic circuit components, and particularly to fluid cooled heat sinks for use in small footprint applications such as, for example, electronic motor controllers.

### BACKGROUND OF THE INVENTION

Electronic controllers need a cooling solution to dissipate heat generated by operation of the electronic circuit components, such as for example electronic transistors. Without such cooling, the heat can damage the electronic circuit components resulting in failure of the electronic controller. Heat dissipation is particularly difficult in applications in which the electronic controller has a relatively small footprint. For example, electronic motor controllers need to be compactly sized for incorporation into the motor structure. The smaller footprint available to transfer and dissipate the heat creates a challenge to achieve the sufficient cooling needed for such small footprint electronic controllers.

In conventional configurations, a fluid cooled heat sink is mounted in thermal communication to an electronics package that includes electronic circuit components that generate heat. The heat sink includes a body that defines a fluid channel having an inlet and an outlet through which a cooling fluid flows. The cooling fluid may be water, hydraulic fluid, or other suitable fluid that is suitable for heat transfer. The cooling fluid flow is inputted into the inlet of the heat sink body, and as the fluid flows through the fluid channel from the inlet to the outlet, the fluid absorbs heat that is generated by the electronic components. Such heat is thereby removed by the outlet fluid flow from the heat sink body.

Many conventional configurations employ a straight wall configuration of the fluid channel through the heat sink body, which provides a low-resistance flow path. However, such a straight wall configuration has disadvantages. Due to the straight wall configuration, a majority or a substantial uneven portion of fluid may flow closer to the straight wall section of the fluid channel which provides a less optimum heat transfer path for the fluid. A conventional straight channel heat sink also does not have enough surface area within the fluid channel to achieve the requisite heat transfer for small footprint applications such as electronic motor controllers. In addition, a conventional straight channel heat sink cannot create uniform distribution and turbulence of fluid inside the heat sink fluid channel, and such lack of uniformity and turbulence results in uneven heat transfer which may be ineffective to achieve sufficient cooling. More complicated fluid channel designs have been proposed to achieve the target heat transfer for sufficient cooling, but such complicated heat sink designs can increase the manufacturing cost of the heat sink and may be unsuitable for small footprint applications.

### SUMMARY OF THE INVENTION

The present application describes an enhanced fluid cooled heat sink design that is particularly suitable for small footprint applications, such as for example the cooling of electronic motor controllers. A fluid cooled heat sink includes a heat sink body that defines a fluid channel having a non-straight channel wall profile, combined with an array of protruding pin fins that are located within at least a portion of the fluid channel. In an exemplary embodiment, the fluid cooled heat sink includes a fluid channel configured with a semicircular wavy wall channel profile having a plurality of adjacent semicircular wall segments, in combination with an array cylindrical pin fins each having a circular cross-sectional shape. With such configuration, a highly turbulent flow with uniform flow distribution is achieved, thereby achieving superior heat transfer efficiency in a smaller footprint as compared to conventional configurations.

The cylindrical pin finned heat sink with a semicircular wavy channel wall profile provides efficient cooling for electronic circuit components, such as for example in an electronic motor controller and other applications, and small footprint applications in particular. In an exemplary embodiment, the channel wall profile of the heat sink fluid channel is configured as adjacent semicircular wall segments peripheral to an array of cylindrical pin fins of circular cross-sectional shape. The shape and position of the channel wall profile with respect to the pin fins is defined in such a way that the cross-sectional space (area) between the wall and a pin fin is the same as the spaces between each of the pin fins, thereby resulting in a constant flow area across each portion of the array of pin fins. This configuration helps to distribute the fluid equally through the entire cross section of the heatsink and eliminate the problem of a bigger portion of flow flowing closer to the channel wall. Thus, with the help of the channel wall profile shape, the flow channel will have constant volume or constant area at each section of the flow elements. The uniform arrangement of pin fins together with the semicircular wavy channel wall profile further provides an optimum fluid distribution inside the fluid channel and increases the surface area in contact with the cooling fluid for better heat transfer, which permits a smaller footprint for the heat sink. The pin fins and the fluid channel wall segments can have other suitable regular shapes so long as the cross-sectional flow area around each pin fin is uniform. For example, diamond, oval, square, hexagonal, or other regularly shaped pin fins and/or channel wall segments may be employed.

The described configuration of arranging the pin fins and the non-straight fluid channel wall segments permits the heat sink to be compact while still achieving the requisite cooling with less pressure drop as compared to conventional configurations. The pin fins can be arranged in different sets of rows and columns having different numbers of pin fins, and also with different pin fin diameters or different pin fin shape to increase the heat transfer capacity of the heat sink. The pin fins and the non-straight heat sink fluid channel wall can be manufactured using sand casting or pressure die casting, which helps reduce the cost of manufacturing and provides a simple configuration with effective heat transfer.

The array of pin fins is arranged in a plurality of rows and columns located within the fluid channel and extending from the channel base, the channel wall being located peripherally relative to the array of pin fins. The channel wall and the array of pin fins are positioned such that there is a constant flow area for the flow of the cooling fluid across each row and column of the plurality of rows and columns. A shortest distance between adjacent pin fins is constant or the same throughout the array of rows and columns of pin fins. Similarly, as to pin fins positioned adjacent to the channel wall, a shortest distance between such a pin fin positioned adjacent to the channel wall and the channel wall is the same as the shortest distance between adjacent pin fins in the rows and columns of the array of pin fins. With such a configuration, there is a constant flow area for the flow of the cooling fluid across each row and column of the plurality of rows and columns in the array of pin fins.

An aspect of the invention, therefore, is an enhanced heat sink having a non straight fluid channel wall profile and an array of pin fins in the fluid channel to provide a more effective heat transfer in a small footprint. In exemplary embodiments, a heat sink includes a heat sink body having a first port and a second port, and the heat sink body defines a fluid channel between the first port and the second port to receive a flow of a cooling fluid between the first port and the second port. The heat sink body includes a channel base and a channel wall that extends from the channel base to define the fluid channel, the channel wall having a plurality of wall segments that form a non-straight channel wall profile. An array of pin fins arranged in a plurality of rows and columns is located within the fluid channel and extend from the channel base, the channel wall being located peripherally relative to the array of pin fins. The channel wall and the array of pin fins are positioned such that there is a constant flow area for the flow of the cooling fluid across each row and column of the plurality of rows and columns.

In an exemplary embodiment, the plurality of wall segments is configured as adjacent semicircular wall segments that form a wavy channel wall profile, and/or the pin fins are cylindrical pin fins having a circular cross-sectional shape.

In an exemplary embodiment, the pin fins in the array have a uniform arrangement whereby each pin fin in the array is equidistantly spaced apart from adjacent pin fins and/or equidistantly spaced apart from the channel wall.

In an exemplary embodiment, the pin fins are rods that have a diamond cross-sectional shape.

In an exemplary embodiment, the pin fins are rods that have an oval cross-sectional shape.

In an exemplary embodiment, each of the wall segments of the plurality of wall segments has a shape correspondence with a cross-sectional shape of the pin fins.

In an exemplary embodiment, each of the wall segments of the plurality of wall segments lacks a shape correspondence with a cross-sectional shape of the pin fins.

In an exemplary embodiment, the plurality of wall segments comprises adjacent semicircular wall segments that form a wavy channel wall profile, and the pin fins are rod pin fins having a diamond cross-sectional shape.

In an exemplary embodiment, the plurality of wall segments comprises adjacent semi-diamond wall segments that form a diamond channel wall profile, and the pin fins are rod pin fins having a diamond cross-sectional shape.

In an exemplary embodiment, the plurality of wall segments comprises adjacent semi-ovular wall segments that form an ovular wavy channel wall profile, and the pin fins are rod pin fins having an oval cross-sectional shape.

In an exemplary embodiment, the pin fins are arranged in different sets of rows and columns having different numbers pin fins.

In an exemplary embodiment, the channel wall and the pin fins extend perpendicularly from the channel base.

In an exemplary embodiment, the channel wall includes a first wall section and a second wall section opposite from the first wall section, and the plurality of wall segments includes opposing wall segments respectively located on the first wall section and the second wall section.

In an exemplary embodiment, the first port and the second port are located on a same side of the heat sink body, and the fluid channel includes a first channel portion and a second channel portion in which the cooling fluid flows in opposite directions, the first channel portion and the second channel portion being connected by a channel bridge and otherwise separated by a central body portion of the heat sink body.

In an exemplary embodiment, the first port and the second port are located on opposite sides of the heat sink body.

In an exemplary embodiment, a shortest distance between adjacent pin fins is constant throughout the array of rows and columns of pin fins, and as to pin fins positioned adjacent to the channel wall, a shortest distance between a pin fin positioned adjacent to the channel wall and the channel wall is the same as the shortest distance between adjacent pin fins in the rows and columns of the array of pin fins

In an exemplary embodiment, the heat sink further includes a cover plate fixed to an outer surface of the heat sink body and that covers an expanse of the fluid channel.

In an exemplary embodiment, the heat sink body includes a recessed shelf formed relative to the outer surface at a step and that extends along a perimeter of an edge of the channel wall opposite from the channel base, the cover plate being received by the recessed shelf.

Another aspect of the invention is an operational assembly including the heat sink according to any of the embodiments mounted to an electronics package having an electronic component that generates heat. In exemplary embodiments of the operational assembly, the heat sink includes a first outer surface and a second outer surface opposite from the first outer surface, and the channel base is an internal surface of the heat sink body in thermal communication with the second outer surface and the array of pin fins extends into the fluid channel from the channel base in a direction opposite from the second outer surface. A cover plate is fixed to the first outer surface of the heat sink body and covers the expanse of the fluid channel. The electronics package is mounted to the second outer surface of the heat sink body, and the electronic component is positioned adjacent to the second outer surface of the heat sink body such that heat generated by the electronic component thermally transfers through the channel base and pin fins to the fluid channel.

These and further features of the present invention will be apparent with reference to the following description and attached drawings. In the description and drawings, particular embodiments of the invention have been disclosed in detail as being indicative of some of the ways in which the principles of the invention may be employed, but it is understood that the invention is not limited correspondingly in scope. Rather, the invention includes all changes, modifications and equivalents coming within the spirit and terms of the claims appended hereto. Features that are described and/or illustrated with respect to one embodiment may be used in the same way or in a similar way in one or more other embodiments and/or in combination with or instead of the features of the other embodiments.

### BRIEF DESCRIPTION OF THE DRAWINGS

FIG. 1 is a drawing depicting a perspective view of an exemplary heat sink in accordance with embodiments of the present application.

FIG. 2 is a drawing depicting a top view of the exemplary heat sink of FIG. 1.

FIG. 2A is a drawing depicting a closeup portion of a heat sink that illustrates a variation on the configuration of FIG. 2, and further illustrating the concept of constant flow area.

FIG. 3 is a drawing depicting the isometric view of the exemplary heat sink of FIG. 1, further depicting an additional cover plate and seal.

FIG. 4 is a drawing depicting a perspective view of the exemplary heat sink of FIGS. 1-3 in combination with an electronics package to which the heat sink is mounted.

FIG. 5 is a drawing depicting a side view of the combination heat sink and electronics package of FIG. 4.

FIG. 6 is a drawing depicting a side cross-sectional view of the combination heat sink and electronics package of FIGS. 4 and 5, further depicting the pin fins.

FIG. 7 is a drawing depicting a perspective view of another exemplary heat sink in accordance with embodiments of the present application.

FIG. 8 is a drawing depicting a top view of the exemplary heat sink of FIG. 7.

FIG. 9 is a drawing depicting the isometric view of the exemplary heat sink of FIG. 7, further depicting an additional cover plate.

FIG. 10 is a drawing depicting a perspective view of another exemplary heat sink in accordance with embodiments of the present application.

FIG. 11 is a drawing depicting a top view of the exemplary heat sink of FIG. 10.

FIG. 12 is a drawing depicting a close-up view of a portion of the heat sink of FIG. 11, further illustrating the concept of constant flow area for the channel wall/pin fin shape combination of FIGS. 10 and 11.

FIG. 13 is a drawing depicting the isometric view of the exemplary heat sink of FIG. 10, further depicting an additional cover plate.

FIG. 14 is a drawing depicting a perspective view of another exemplary heat sink in accordance with embodiments of the present application.

FIG. 15 is a drawing depicting a top view of the exemplary heat sink of FIG. 14.

FIG. 16 is a drawing depicting a close-up view of a portion of the heat sink of FIG. 14, further illustrating the concept of constant flow area for the channel wall/pin fin shape combination of FIGS. 14 and 15.

FIG. 17 is a drawing depicting the isometric view of the exemplary heat sink of FIG. 14, further depicting an additional cover plate.

### DETAILED DESCRIPTION

Embodiments of the present application will now be described with reference to the drawings, wherein like reference numerals are used to refer to like elements throughout. It will be understood that the figures are not necessarily to scale.

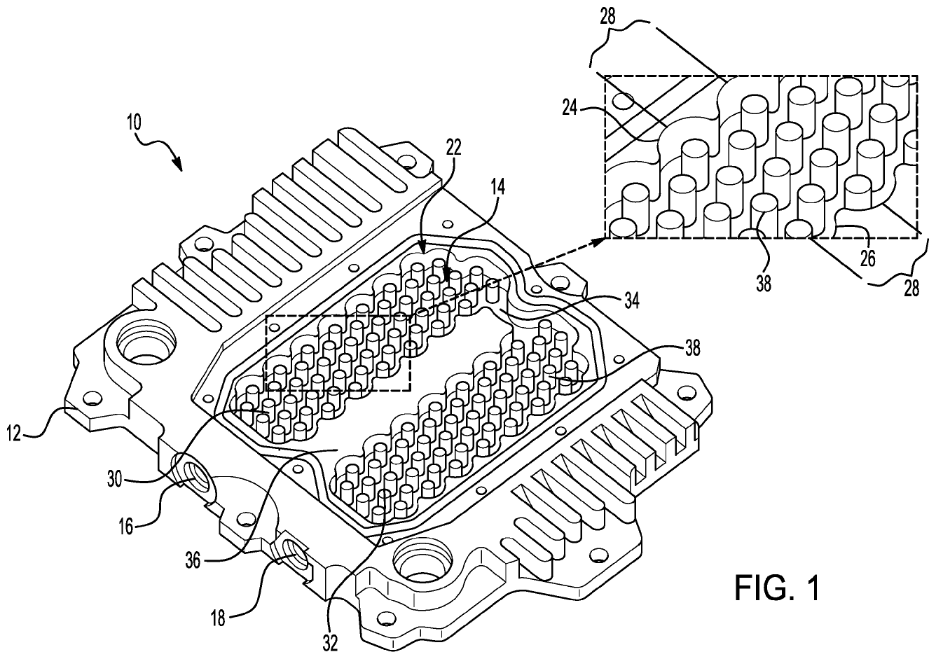

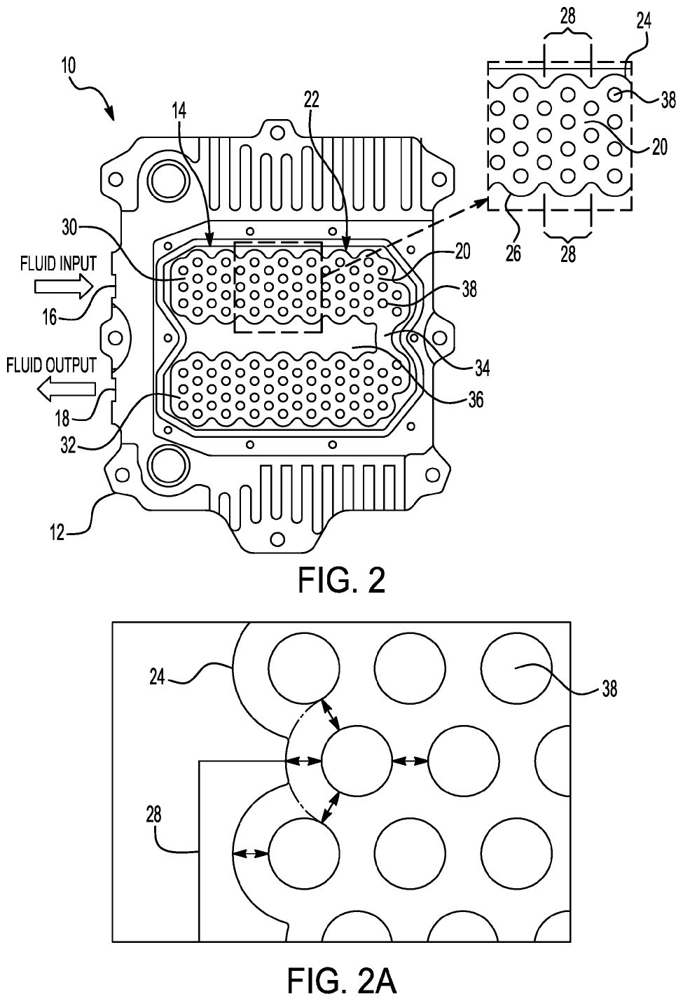

FIG. 1 is a drawing depicting a perspective view of an exemplary heat sink 10 in accordance with embodiments of the present application. FIG. 2 is a drawing depicting a top view of the exemplary heat sink 10 of FIG. 1. The heat sink 10 includes a heat sink body 12 that defines a fluid channel 14 that extends through the heat sink body 12. The heat sink body 12 includes a first port 16 and a second port 18 in fluid communication with the fluid channel 14. As further detailed below, in operation to dissipate heat a cooling fluid flows through the fluid channel 14 between the first port 16 and the second port 18. In the specific depiction of FIG. 2, the first port 16 is an inlet port for an input flow of the cooling fluid and the second port 18 is an outlet port for an output flow of the cooling fluid, although the inlet and outlet ports can be reversed from the depiction in FIG. 2. Materials used to manufacture the heat sink 10 may be any material which has a high thermal conductivity. Suitable examples include copper and aluminum, with aluminum being a particularly cost effective material option for many applications.

In defining the fluid channel 14, the heat sink body includes a channel base 20 (the channel base 20 is best visible in the top viewpoint of FIG. 2) and a channel wall 22 that extends from the channel base 20. The channel wall 22 may extend perpendicularly from the channel base 20. The channel wall 22 has a non-straight channel wall profile in a direction parallel to a plane of the channel base 20. Looking at the close-up portion in FIGS. 1 and 2, in the example depicted in FIGS. 1 and 2 the channel wall profile includes a first wall section 24 and a second wall section 26 opposite from the first wall section 24. In this example, the non-straight channel wall profile is configured as a semicircular wavy channel wall profile in which each of the wall sections 24 and 26 is configured as adjacent semicircular wall segments 28, whereby semicircular wall segments 28 of the first wall section 24 are positioned oppositely from corresponding semicircular wall segments 28 of the second wall section 26. Further in the example depicted in FIGS. 1 and 2, to minimize the footprint of the heat sink the first port 16 and the second port 18 are located on a same side of the heat sink body 12. With such configuration, the fluid channel 14 includes a first channel portion 30 and a second channel portion 32 in which the cooling fluid flows in opposite directions. The first channel portion 30 and the second channel portion 32 are connected by a channel bridge 34 and otherwise are separated from each other by a central body portion 36 of the heat sink body 12.

The channel wall 22 is positioned peripheral to an array of pin fins 38 that extend from the channel base 20. The pin fins 38 may extend perpendicularly from the channel base 20. In the example of FIGS. 1 and 2, each of the pin fins 38 is a cylindrical pin fin of circular cross-sectional shape that extends perpendicularly from the channel base 20. The pin fins in the array may have a uniform distribution arrangement whereby each pin fin 38 in the array is equidistantly spaced apart from adjacent pin fins.

The configuration of a non-straight channel wall profile, such as for example including adjacent semicircular wall segments, increases the turbulence inside the fluid channel and thus improves the efficiency of heat transfer. The additional arrangement of pin fins combined together with the semicircular wavy channel wall profile further provides an optimum fluid distribution inside the fluid channel and increases the surface area in contact with the cooling fluid for better heat transfer. More generally, the shape and position of the channel wall profile with respect to the pin fins is defined in such a way that the cross-sectional space (area) between the channel wall and a pin fin is the same as the spaces between each of the pin fins. This configuration helps to distribute the fluid equally through the entire cross section of the heatsink and eliminates the problem of a bigger portion of flow flowing closer to the channel wall. Thus, with the help of the channel wall profile shape, the flow channel will have constant volume or constant area at each section of the flow channel. The described configuration of arranging the pin fins and the non-straight fluid channel wall segments permits the heat sink to be compact while still achieving the requisite cooling with less pressure drop as compared to conventional configurations. The pin fins can be arranged in different sets of rows and columns with different numbers of pin fins, as seen in FIGS. 1 and 2 which depict an example of alternating rows of three versus four pin fins. The pin fins also may have different pin fin diameters to increase the heat transfer capacity of the heat sink. The pin fins and the non-straight heat sink fluid channel wall can be manufactured using sand casting or pressure die casting, which helps to reduce the cost of manufacturing and provides a simple configuration with effective heat transfer in a small footprint.

Accordingly, the array of pin fins is arranged in a plurality of rows and columns located within the fluid channel and extending from the channel base, the channel wall being located peripherally relative to the array of pin fins. The channel wall and the array of pin fins are positioned such that there is a constant flow area for the flow of the cooling fluid across each row and column of the plurality of rows and columns.

FIG. 2A is a drawing depicting a closeup portion of a heat sink that illustrates a variation on the configuration of FIG. 2, and further illustrating the concept of constant flow area across the heat sink. As seen in FIG. 2A, a shortest distance between adjacent pin fins as illustrated by the arrows is constant or the same throughout the array of rows and columns of pin fins. Similarly, as to pin fins positioned adjacent to the channel wall, such as for example positioned adjacent to the first wall section 24 of the channel wall 22 shown in FIG. 2A, as further illustrated by the arrows a shortest distance between such a pin fin positioned adjacent to the channel wall and the channel wall is the same as the shortest distance between adjacent pin fins in the rows and columns of the array of pin fins. With such a configuration, there is a constant flow area for the flow of the cooling fluid across each row and column of the plurality of rows and columns in the array of pin fins employing circular-based shaped pin fins and channel wall profile.

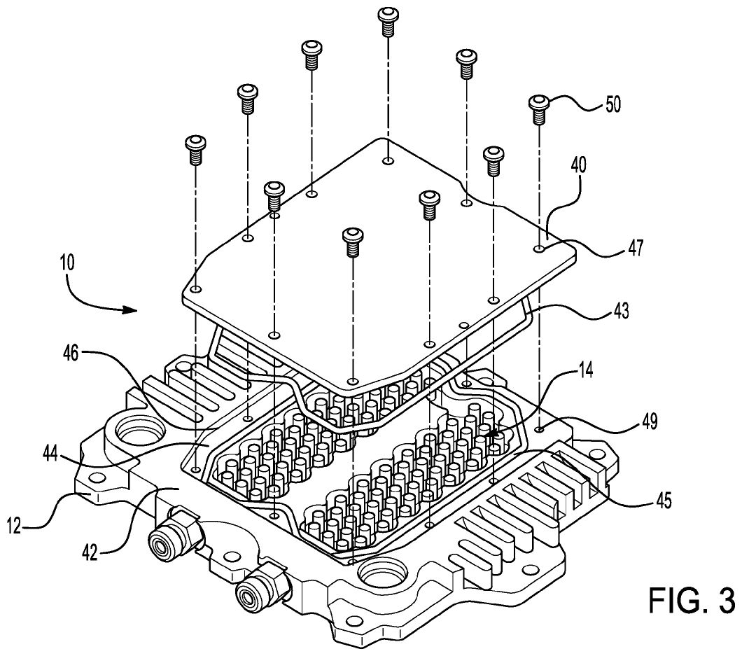

FIG. 3 is a drawing depicting the isometric view of the exemplary heat sink 10 of FIG. 1, further depicting an additional cover plate 40 and seal 43. The heat sink body 12 has a first outer surface 42 and a recessed shelf 44 formed relative to the first outer surface 42 at a step 46. The recessed shelf 44 extends along a perimeter of an edge of the channel wall 22 opposite from the channel base 20. The recessed shelf 44 is shaped to receive the cover plate 40 whereby the cover plate 40 covers the expanse of the fluid channel 14, with the cover plate 40 being flush with the first outer surface 42 when the cover plate 40 is received within the recessed shelf 44. Once properly positioned, the cover plate 40 is fixed to the recessed shelf 44. The cover plate 40 and the recessed shelf 44 respectively may have aligned fastening holes 47 and 49 for receiving fastening elements 50, which may be bolts, screws, or other suitable fasteners. As another example, the cover plate 40 may be fixed to the recessed shelf 44 using an adhesive or like material that adheres or bonds the cover plate to the recessed shelf. There also may be a seal 43, for example an O-ring seal, to seal the contact surfaces of the recessed shelf 44 and cover 40 to prevent the leakage of fluid from the heat sink. The recessed shelf 44 has a grove 45 in which to locate the O-ring seal 43.

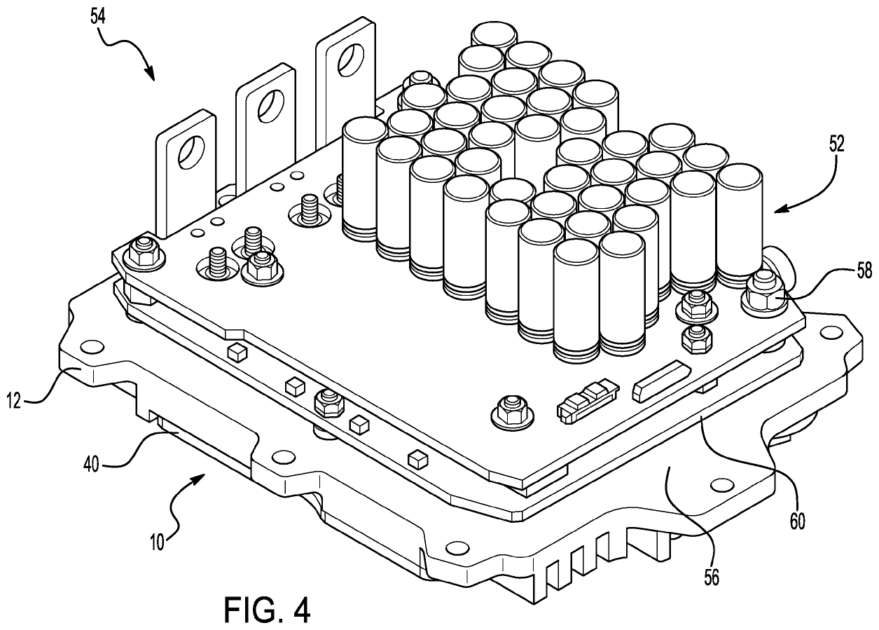

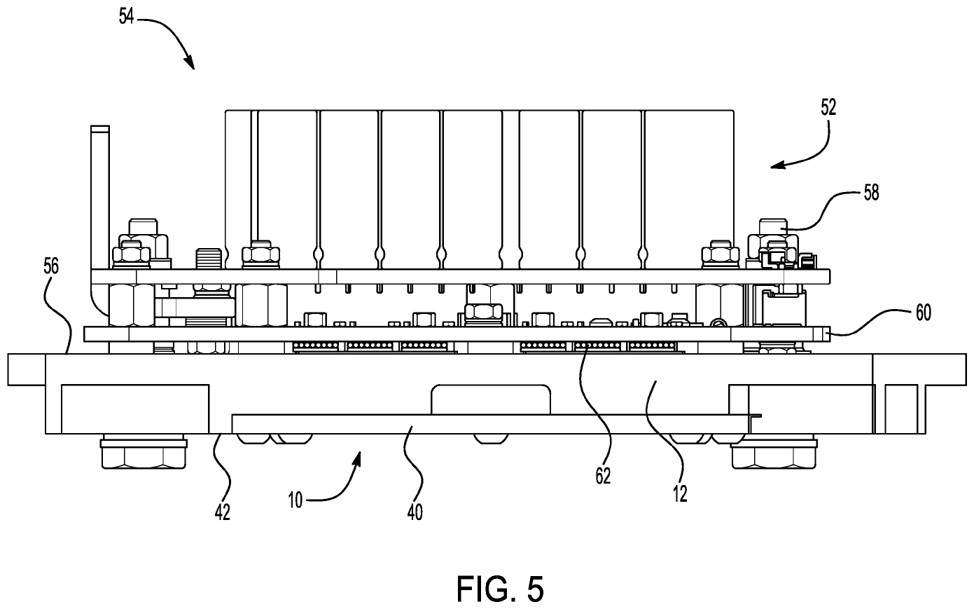

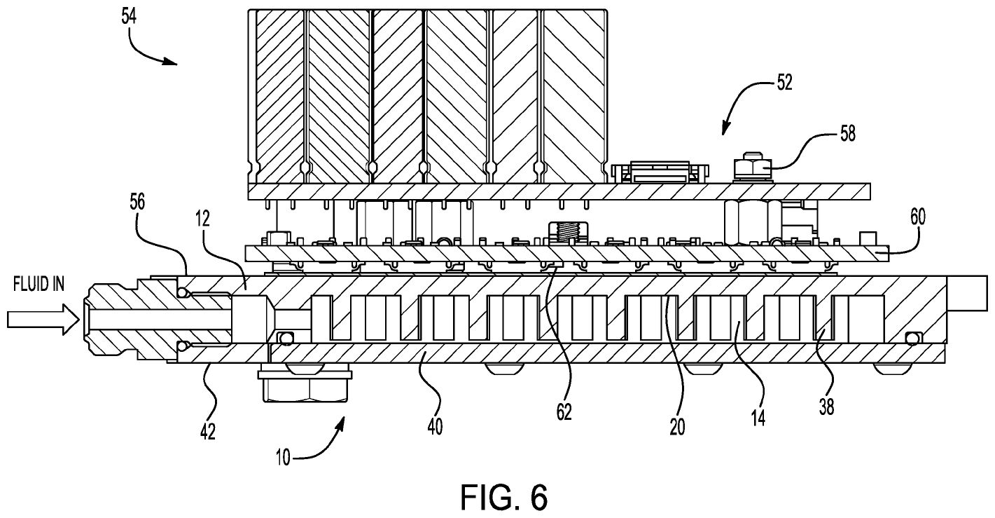

FIG. 4 is a drawing depicting a perspective view of the exemplary heat sink 10 of FIG. 1 in combination with an electronics package 52 to which the heat sink 10 is mounted to form an operational assembly 54. FIG. 5 is a drawing depicting a side view of the operational assembly 54 including the combination of the heat sink 10 and electronics package 52 of FIG. 4. FIG. 6 is a drawing depicting a cross-sectional view the operational package 54 including the combination of the heat sink and electronics package of FIGS. 4 and 5, further depicting the pin fins as located relative to the electronics package. The electronics package includes one or more electronic circuit components that generate heat during use. As referenced above, one example application is the electronic controller for an electric motor, and the electronic controller includes one or more electronic circuit components, such as for example transistors, that generate heat. As further detailed below, the heat sink operates to dissipate heat generated by the electronic circuit components. In addition, although the heat sink 10 is described principally in connection with dissipating heat from electronic components, the heat sink is not limited to the application of electronic components, and otherwise may be employed in any application which needs heat to be removed from the system.

The electronics package 52 is mounted to a second outer surface 56 of the heating sink body 12, the second outer surface 56 being positioned oppositely from the first outer surface 42 and the cover plate 40. The electronics package 52 is mounted to the heat sink 10 at the second outer surface 56 using fasteners 58, which also may be bolts, screws, or other suitable fasteners. The electronics package 52 includes a support board 60 to which there are attached one or more electronic circuit components 62 (see particularly FIGS. 5 and 6) that generate heat. As referenced above, an example application is an electronic controller that includes transistors as the electronic circuit component(s) 62 that generates heat, although as referenced above the heat sink 10 may be employed to dissipate heat from any suitable heat-generating device.

Referring to the cross-sectional view of FIG. 6 in particular, the second outer surface 56 and the channel base 20 are opposing surfaces of an outer portion of the heat sink body 12. With such configuration, the channel base 20 is an internal surface of the heat sink body in thermal communication with the second outer surface 56. The pin fins 38 extend into the fluid channel 14 from the channel base 20 in a direction opposite from the second outer surface 56. The electronics package 52 is fixed to the outer surface 56 of the heat sink body 12, with the heat generating electronic circuit component 62 being positioned against or adjacent to the second outer surface 56 of the heat sink body 12.

In operation, a cooling fluid (such as for example water, hydraulic fluid, or other suitable cooling fluid), is inputted to the first port 16 and into the fluid channel 14, and the cooling fluid flows through the fluid channel 14 to the second port 18. As the one or more electronic circuit components 62 operate, heat generated by the electronic circuit component(s) thermally transfers into the heat sink body 12 through the outer surface 56 at the location of the electronic circuit component(s). The heat transfers to the channel wall 22 and through the pin fins 38 to the fluid channel 14. The cooling fluid flowing around the pin fins absorbs the heat, which is removed from the heat sink by the output flow of the cooling fluid through the second port 18. As referenced above, the configuration of a non-straight channel wall profile, such as including adjacent wavy semicircular wall segments, increases the turbulence inside the fluid channel and thus improves the efficiency of heat transfer. The additional arrangement of the pin fins combined together with the non-straight channel wall profile further provides an optimum fluid distribution inside the fluid channel, and increases the surface area in contact with the cooling fluid for better heat transfer. The distribution is enhanced by providing a uniform arrangement of pin fins in the array, in which the pin fins are arranged in regular rows and/or columns, and/or with a uniform distribution arrangement whereby each pin fin in the array is equidistantly spaced apart from adjacent pin fins and/or equidistantly spaced apart from the channel wall. With such a configuration, there is a constant flow area for the flow of the cooling fluid across each row and column of the plurality of rows and columns in the array of pin fins.

The pin fins and the fluid channel wall segments may have other suitable regular shapes so long as the cross-sectional flow area around each pin fin is uniform. Diamond, square, hexagonal, oval, or other regularly shaped pin fins and/or channel wall segments may be employed. As referenced above, the shape and position of the channel wall profile with respect to the pin fins is defined in such a way that the cross-sectional space (area) between the channel wall and a pin fin is the same as the spaces between each of the pin fins. This configuration helps to distribute the fluid equally through the entire cross section of the heatsink and eliminates the problem of a bigger portion of flow flowing closer to the channel wall. Thus, with the help of the channel wall profile shape, the flow channel will have constant volume or constant area at each section of the flow elements.

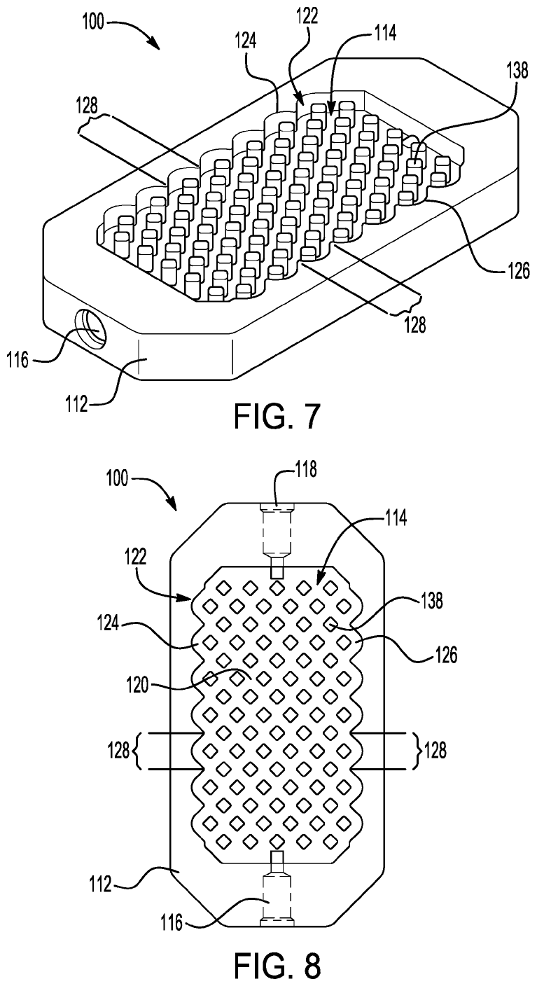

Accordingly, any suitable combination of channel wall profile and pin fin cross-sectional shape that meets such criteria may be employed. For example, FIG. 7 is a drawing depicting a perspective view of another exemplary heat sink 100 in accordance with embodiments of the present application, and FIG. 8 is a drawing depicting a top view of the exemplary heat sink 100 of FIG. 7. The configuration of the heat sink 100 bears similarities to the heat sink 10 of FIGS. 1-6, except that the heat sink 100 employs a different shaped configuration of the pin fins. Accordingly, the heat sink 100 includes a heat sink body 112 that defines a fluid channel 114 that extends through the heat sink body 112. The heat sink body 112 includes a first port 116 and a second port 118 in fluid communication with the fluid channel 114 for the flow of the cooling fluid. In the previous embodiment, the first and second ports were located on a same side of the heat sink body. In the variation of FIGS. 7 and 8, and first and second ports 116, 118 are located on opposite sides of the heat sink body 112 with the cooling fluid proceeding through the heat sink body from the first port 116 to the second port 118 (or vice versa).

In defining the fluid channel 114, the heat sink body 112 includes a channel base 120 (the channel base 120 is best visible in the top viewpoint of FIG. 8) and a channel wall 122 that extends from the channel base 120. The channel wall 122 may extend perpendicularly from the channel base 120. Similarly as in the previous embodiment, in the example of FIGS. 7 and 8 the channel wall 122 has a non-straight channel wall profile in a direction parallel to a plane of the channel base 120, configured as a semicircular wavy channel wall profile in which each of opposing walls sections 124 and 126 are configured as adjacent semicircular wall segments 128, whereby semicircular wall segments 128 of the first wall section 124 are positioned oppositely from corresponding semicircular wall segments 128 of the second wall section 126.

The channel wall 122 is positioned peripheral to an array of pin fins 138 that extend from the channel base 120. The pin fins 138 may extend perpendicularly from the channel base 120. In the example of FIGS. 7 and 8, each of the pin fins 138 is a rod pin fin of diamond cross-sectional shape that extends perpendicularly from the channel base 120. The pin fins in the array may have a uniform distribution arrangement whereby each pin fin 138 in the array is equidistantly spaced apart from adjacent pin fins and/or equidistantly spaced apart from the channel wall. The array of pin fins also may be arranged in rows of different numbers of pins fins. In one embodiment, the wall segments that form the channel wall profile each has a shape correspondence with a cross-sectional shape of the pin fins, i.e., a semicircular wall segment shape is combined with circular cross-sectional pin fins as in FIGS. 1 and 2, or a half-diamond wall segment shape is combined with diamond cross-sectional pin fins. Alternatively, in another embodiment the wall segments that form the channel wall profile each has a shape that lacks shape correspondence with a cross-sectional shape of the pin fins, i.e., a semicircular wall segment shape is combined with diamond cross-sectional pin fins as in FIGS. 7 and 8.

With such channel wall/pin fin shape combination, similarly as in the previous embodiment, a shortest distance between adjacent pin fins is constant or the same throughout the array of rows and columns of pin fins. Similarly, as to pin fins positioned adjacent to the channel wall, a shortest distance between such a pin fin positioned adjacent to the channel wall and the channel wall is the same as the shortest distance between adjacent pin fins in the rows and columns of the array of pin fins. With such a configuration, there is a constant flow area for the flow of the cooling fluid across each row and column of the plurality of rows and columns in the array of pin fins employing diamond-based shaped pin fins and semi-circular channel wall profile.

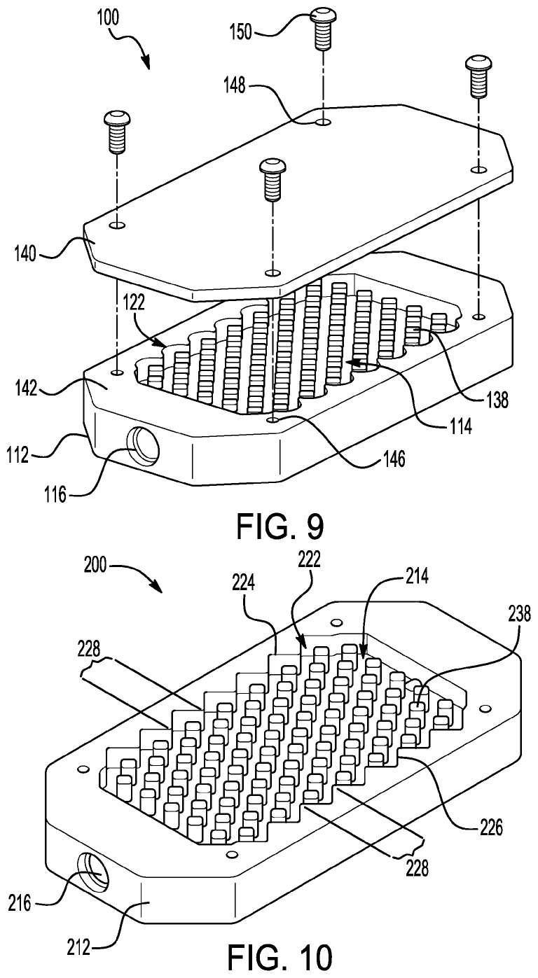

FIG. 9 is a drawing depicting the isometric view of the exemplary heat sink 100 of FIG. 7, further depicting an additional cover plate 140. In this example, the heat sink body 112 has a first outer surface 142 shaped to receive the cover plate 140, whereby the cover plate 140 covers the expanse of the fluid channel 114. In this example, the cover plate 140 is fastened or otherwise fixed directly over essentially the entire expanse of the outer surface 142 (i.e., no recessed shelf is used in this embodiment in contrast to the previous embodiment). The cover plate 140 and the outer surface 142 respectively may have aligned fastening holes 146 and 148 for receiving fastening elements 150, which may be bolts, screws, or other suitable fasteners. As another example, the cover plate 140 may be fixed to the outer surface 142 using an adhesive or like material that adheres or bonds the cover plate to the heat sink body. Once assembled with the cover plate, the heat sink 100 can be fixed to an electronics package to remove or dissipate heat generated by one or more electronic components of the electronics package, comparably as described above in connection with FIGS. 4-6.

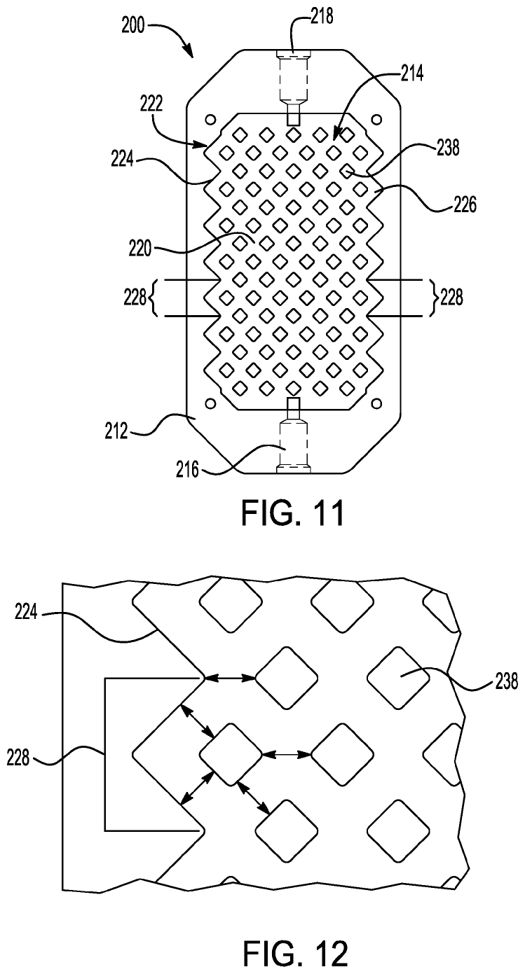

As another example of a different shape configuration of pin fins and channel wall profile combination, FIG. 10 is a drawing depicting a perspective view of another exemplary heat sink 200 in accordance with embodiments of the present application, and FIG. 11 is a drawing depicting a top view of the exemplary heat sink 200 of FIG. 10. The heat sink 200 includes a heat sink body 212 that defines a fluid channel 214 that extends through the heat sink body 212. The heat sink body 212 includes a first port 216 and a second port 218 in fluid communication with the fluid channel 214 for the flow of the cooling fluid. In the variation of FIGS. 10 and 11, and first and second ports 216, 218 also are located on opposite sides of the heat sink body 212 with the cooling fluid proceeding through the heat sink body from the first port 216 to the second port 218 (or vice versa).

In defining the fluid channel 214, the heat sink body 212 includes a channel base 220 (the channel base 220 is best visible in the top viewpoint of FIG. 11) and a channel wall 222 that extends from the channel base 220. The channel wall 222 may extend perpendicularly from the channel base 220. In the example of FIGS. 10 and 11 the channel wall 222 has a non-straight channel wall profile in a direction parallel to a plane of the channel base 220, configured as a semi-diamond channel wall profile in which each of opposing walls sections 224 and 226 is configured as adjacent semi-diamond wall segments 228, whereby semi-diamond wall segments 228 of the first wall section 224 are positioned oppositely from corresponding semi-diamond wall segments 228 of the second wall section 226.

The channel wall 222 is positioned peripheral to an array of pin fins 238 that extend from the channel base 220. The pin fins 238 may extend perpendicularly from the channel base 220. In the example of FIGS. 10 and 11, each of the pin fins 238 is a rod pin fin of diamond cross-sectional shape that extends perpendicularly from the channel base 220. The pin fins in the array may have a uniform distribution arrangement whereby each pin fin 238 in the array is equidistantly spaced apart from adjacent pin fins and/or equidistantly spaced apart from the channel wall.

Similarly as in previous embodiments, therefore, the array of pin fins is arranged in a plurality of rows and columns located within the fluid channel and extending from the channel base, the channel wall being located peripherally relative to the array of pin fins. The channel wall and the array of pin fins are positioned such that there is a constant flow area for the flow of the cooling fluid across each row and column of the plurality of rows and columns. FIG. 12 is a drawing depicting a portion of the heat sink of FIG. 11, further illustrating the concept of constant flow area for the channel wall/pin fin shape combination of FIGS. 10 and 11. As seen in FIG. 12, a shortest distance between adjacent pin fins is constant or the same throughout the array of rows and columns of pin fins. Similarly, as to pin fins positioned adjacent to the channel wall, such as for example positioned adjacent to the first wall section 224 of the channel wall 222 shown in FIG. 12, a shortest distance between such a pin fin positioned adjacent to the channel wall and the channel wall is the same as the shortest distance between adjacent pin fins in the rows and columns of the array of pin fins. With such a configuration, there is a constant flow area for the flow of the cooling fluid across each row and column of the plurality of rows and columns in the array of pin fins employing diamond-based shaped pin fins and channel wall profile.

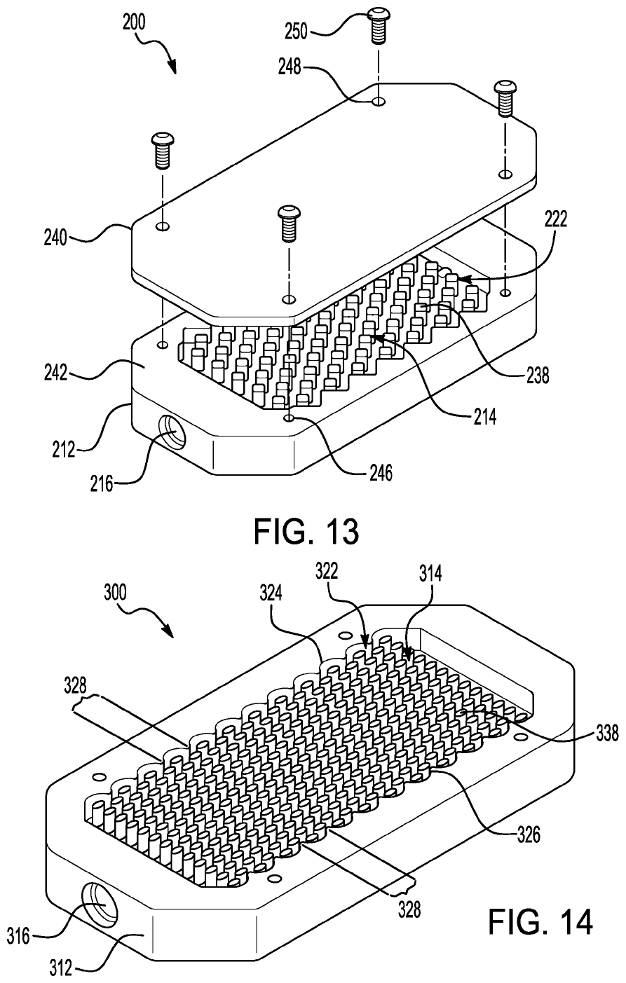

FIG. 13 is a drawing depicting the isometric view of the exemplary heat sink 200 of FIG. 10, further depicting an additional cover plate 240. In this example, the heat sink body 212 has a first outer surface 242 shaped to receive the cover plate 240, whereby the cover plate 240 covers the expanse of the fluid channel 214. In this example, the cover plate 240 also is fastened or otherwise fixed directly over essentially the entire expanse of the outer surface 242. The cover plate 240 and the outer surface 242 respectively may have aligned fastening holes 246 and 248 for receiving fastening elements 250, which may be bolts, screws, or other suitable fasteners. As another example, the cover plate 240 may be fixed to the outer surface 242 using an adhesive or like material that adheres or bonds the cover plate to the heat sink body. Once assembled with the cover plate, the heat sink 200 can be fixed to an electronics package to remove or dissipate heat generated by one or more electronic components of the electronics package, comparably as described above in connection with FIGS. 4-6.

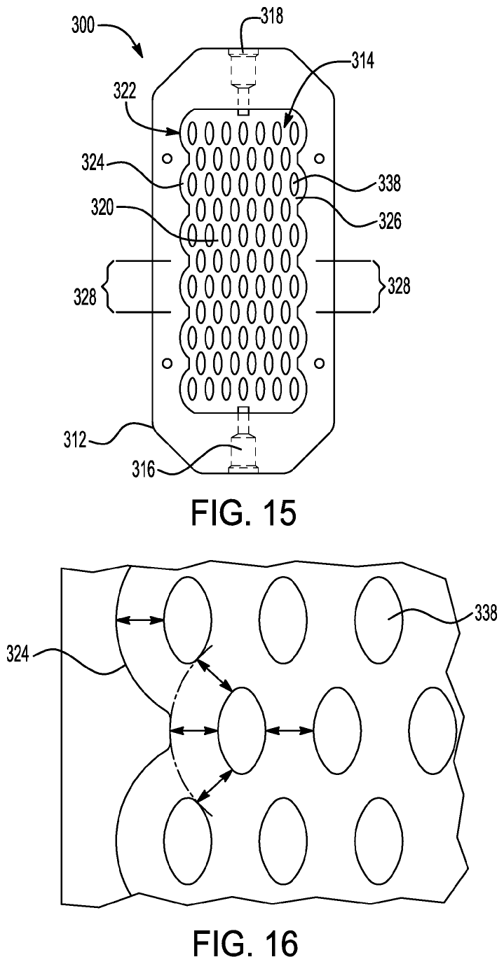

As another example of a different shape configuration of pin fins and channel wall profile combination, FIG. 14 is a drawing depicting a perspective view of another exemplary heat sink 300 in accordance with embodiments of the present application, and FIG. 15 is a drawing depicting a top view of the exemplary heat sink 300 of FIG. 14. The heat sink 300 includes a heat sink body 312 that defines a fluid channel 314 that extends through the heat sink body 312. The heat sink body 312 includes a first port 316 and a second port 318 in fluid communication with the fluid channel 314 for the flow of the cooling fluid. In the variation of FIGS. 14 and 15, and first and second ports 316, 318 also are located on opposite sides of the heat sink body 312 with the cooling fluid proceeding through the heat sink body from the first port 316 to the second port 318 (or vice versa).

In defining the fluid channel 314, the heat sink body 312 includes a channel base 320 (the channel base 320 is best visible in the top viewpoint of FIG. 15) and a channel wall 322 that extends from the channel base 320. The channel wall 322 may extend perpendicularly from the channel base 320. In the example of FIGS. 14 and 15, the channel wall 322 has a non-straight channel wall profile in a direction parallel to a plane of the channel base 320, configured as a semi-oval channel wall profile in which each of opposing walls sections 324 and 326 is configured as adjacent semi-ovular wall segments 328, whereby semi-ovular wall segments 328 of the first wall section 324 are positioned oppositely from corresponding semi-ovular wall segments 328 of the second wall section 326.

The channel wall 322 is positioned peripheral to an array of pin fins 338 that extend from the channel base 320. The pin fins 338 may extend perpendicularly from the channel base 320. In the example of FIGS. 14 and 15, each of the pin fins 338 is a rod pin fin of an oval cross-sectional shape that extends perpendicularly from the channel base 320. The pin fins in the array may have a uniform distribution arrangement whereby each pin fin 338 in the array is equidistantly spaced apart from adjacent pin fins and/or equidistantly spaced apart from the channel wall.

Similarly as in previous embodiments, therefore, the array of pin fins is arranged in a plurality of rows and columns located within the fluid channel and extending from the channel base, the channel wall being located peripherally relative to the array of pin fins. The channel wall and the array of pin fins are positioned such that there is a constant flow area for the flow of the cooling fluid across each row and column of the plurality of rows and columns. FIG. 16 is a drawing depicting a portion of the heat sink of FIG. 15, further illustrating the concept of constant flow area for the ovular channel wall/pin fin shape combination of FIGS. 14 and 15. As seen in FIG. 16, a shortest distance between adjacent pin fins is constant or the same throughout the array of rows and columns of pin fins. Similarly, as to pin fins positioned adjacent to the channel wall, such as for example positioned adjacent to the first wall section 324 of the channel wall 322 shown in FIG. 16, a shortest distance between such a pin fin positioned adjacent to the channel wall and the channel wall is the same as the shortest distance between adjacent pin fins in the rows and columns of the array of pin fins. With such a configuration, there is a constant flow area for the flow of the cooling fluid across each row and column of the plurality of rows and columns in the array of pin fins employing ovular-based shaped pin fins and wall section.

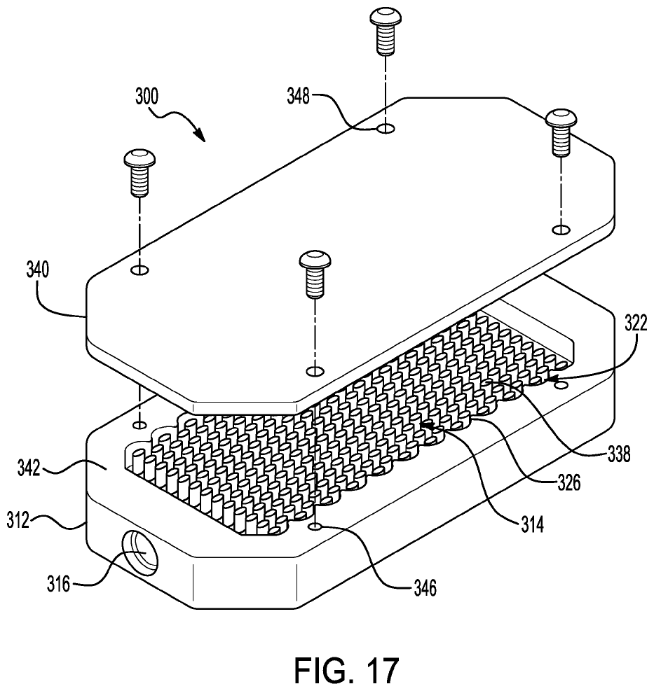

FIG. 17 is a drawing depicting the isometric view of the exemplary heat sink 300 of FIG. 14, further depicting an additional cover plate 340. In this example, the heat sink body 312 has a first outer surface 342 shaped to receive the cover plate 340, whereby the cover plate 340 covers the expanse of the fluid channel 314. In this example, the cover plate 340 also is fastened or otherwise fixed directly over essentially the entire expanse of the outer surface 342. The cover plate 340 and the outer surface 342 respectively may have aligned fastening holes 346 and 348 for receiving fastening elements 350, which may be bolts, screws, or other suitable fasteners. As another example, the cover plate 340 may be fixed to the outer surface 342 using an adhesive or like material that adheres or bonds the cover plate to the heat sink body. Once assembled with the cover plate, the heat sink 300 can be fixed to an electronics package to remove or dissipate heat generated by one or more electronic components of the electronics package, comparably as described above in connection with FIGS. 4-6.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

1. A heat sink comprising:
a heat sink body having a first port and a second port, and the heat sink body defines a fluid channel between the first port and the second port to receive a flow of a cooling fluid between the first port and the second port;
wherein the heat sink body includes a channel base and a channel wall that extends from the channel base to define the fluid channel, the channel wall comprising a plurality of wall segments that form a non-straight channel wall profile; and
an array of pin fins arranged in a plurality of rows and columns located within the fluid channel and that extend from the channel base, the channel wall being located peripherally relative to the array of pin fins;
wherein the channel wall and the array of pin fins are positioned in a pattern that creates a uniform and symmetrical cross-section such that there is a constant flow area which creates a uniform and turbulent flow of the cooling fluid across each row and column of the plurality of rows and columns regardless of where on the heat sink body the first and second ports are located.

2. The heat sink of claim 1, wherein the plurality of wall segments comprises adjacent semicircular wall segments that form a wavy channel wall profile.

3. The heat sink of claim 1, wherein the pin fins are cylindrical pin fins having a circular cross-sectional shape.

4. The heat sink of claim 1, wherein the pin fins are rods that have a diamond cross-sectional shape.

5. The heat sink of claim 1, wherein each of the wall segments of the plurality of wall segments has a shape correspondence with a cross-sectional shape of the pin fins.

6. The heat sink of claim 5, wherein the plurality of wall segments comprises adjacent semicircular wall segments that form a wavy channel wall profile, and the pin fins are cylindrical pin fins having a circular cross-sectional shape.

7. The heat sink of claim 5, wherein the plurality of wall segments comprises adjacent semi-diamond wall segments that form a diamond channel wall profile, and the pin fins are rod pin fins having a diamond cross-sectional shape.

8. The heat sink of claim 5, wherein the plurality of wall segments comprises adjacent semi-ovular wall segments that form an ovular channel wall profile, and the pin fins are rod pin fins having an oval cross-sectional shape.

9. The heat sink of claim 1, wherein each of the wall segments of the plurality of wall segments lacks a shape correspondence with a cross-sectional shape of the pin fins.

10. The heat sink of claim 9, wherein the plurality of wall segments comprises adjacent semicircular wall segments that form a wavy channel wall profile, and the pin fins are rod pin fins having a diamond cross-sectional shape.

11. The heat sink of claim 1, wherein the pin fins in the array have a uniform arrangement whereby each pin fin in the array is equidistantly spaced apart from adjacent pin fins and/or equidistantly spaced apart from the channel wall.

12. The heat sink of claim 1, wherein the pin fins are arranged in different sets of rows and columns having different numbers of pin fins.

13. (canceled)

14. The heat sink of claim 1, wherein the channel wall includes a first wall section and a second wall section opposite from the first wall section, and the plurality of wall segments includes opposing wall segments respectively located on the first wall section and the second wall section.

15. The heat sink of claim 1, wherein the first port and the second port are located on a same side of the heat sink body, and the fluid channel includes a first channel portion and a second channel portion in which the cooling fluid flows in opposite directions, the first channel portion and the second channel portion being connected by a channel bridge and otherwise separated by a central body portion of the heat sink body.

16. The heat sink of claim 1, wherein the first port and the second port are located on opposite sides of the heat sink body.

17. The heat sink according to claim 1, wherein a shortest distance between adjacent pin fins is constant throughout the array of rows and columns of pin fins, and as to pin fins positioned adjacent to the channel wall, a shortest distance between a pin fin positioned adjacent to the channel wall and the channel wall is the same as the shortest distance between adjacent pin fins in the rows and columns of the array of pin fins.

18. The heat sink of claim 1, further comprising a cover plate fixed to an outer surface of the heat sink body and that covers an expanse of the fluid channel; and
wherein the heat sink body includes a recessed shelf formed relative to the outer surface at a step and that extends along a perimeter of an edge of the channel wall opposite from the channel base, the cover plate being received by the recessed shelf.

19. (canceled)

20. An operational assembly comprising:
the heat sink according to claim 1, the heat sink including a first outer surface and a second outer surface opposite from the first outer surface, and the channel base is an internal surface of the heat sink body in thermal communication with the second outer surface and the array of pin fins extends into the fluid channel from the channel base in a direction opposite from the second outer surface;
a cover plate fixed to the first outer surface of the heat sink body and that covers an expanse of the fluid channel; and
an electronics package mounted to the second outer surface of the heat sink body, the electronics package including an electronic component that generates heat, the electronic component being positioned adjacent to the second outer surface of the heat sink body such that heat generated by the electronic component thermally transfers through the channel base and pin fins to the fluid channel.

21. The operational assembly of claim 20, wherein the channel base and the second outer surface are opposing surfaces of an outer portion of the heat sink body.

22. The operational assembly of claim 20, wherein the heat sink body includes a recessed shelf formed relative to the first outer surface at a step and that extends along a perimeter of an edge of the channel wall opposite from the channel base, the cover plate being received by the recessed shelf.
